(19) United States
(12) Patent Application Publication
(10) Pub. No.: US 2009/0090927 A1
(43) Pub. Date: Apr. 9, 2009

(54) Structure of light emitted diode package

(75) Inventors: Peter Pan, Sansia Township (TW); Abram Chang, Taipei City (TW); Yu-Feng Lin, Banciao City (TW)

Correspondence Address: Joe McKinney Muncy, PO Box 1364, Fairfax, VA, 22038-1364, US

(73) Assignee: Everlight Electronics Co., Ltd.

(21) Appl. No.: 12/003,835

(22) Filed: Jan. 2, 2008

(30) Foreign Application Priority Data
Oct. 3, 2007 (TW) 96216540

(51) Int. Cl. H01L 33/00

(52) U.S. Cl. 257/99; 257/E33.001

(57) ABSTRACT

A structure of light emitted diode package including a lead frame, a holder coupled on an end of the lead frame, a LED chip disposed on the holder, a lower sealing portion made by injection molding a first resin material to grab one end of lead frame with the LED chip in order to hold the lead frame and an upper sealing portion made by casting by a second resin material to dispose on the top of the lower sealing portion.

### RELATED APPLICATIONS

This application claims priority to Taiwan Application Serial Number 96216540, filed Oct. 3, 2007, which is herein incorporated by reference.

### BACKGROUND

1. Field of Invention

The present invention is related to a structure of light emitted diode package, and more particularly to a structure of light emitted diode package with two different resin materials of sealing portions.

2. Description of Related Art

The conventional art of LED package, such as a lamp type of high power LED is usually sealed by epoxy resins as a plastic material of a LED sealing package. However, lights containing ultraviolet light waves from the LED, especially white/blue light LED, damages the epoxy resins of the LED sealing package to make it gloomy, thus blocking the lights emitted from LED therein to lessen the volume of emitting light in efficacy.

In view of the drawback described above, a solution has been chosen to use silicone as a plastic material instead of epoxy resins for making the LED sealing package because the material of silicone for a LED sealing package is not notably damaged by lights with ultraviolet light waves. However, although the material of silicone for LED sealing package is strong enough for engaging in a LED with ultraviolet light, it is weaker than the material of epoxy resins for LED sealing package on mounting with a LED chip and a lead frame while the LED product is being assembled or carried. Furthermore, the price of the material of silicone is much higher than the price of epoxy resins. Based on this, people in the related industry need a better solution to cut down the cost from materials of silicone for LED sealing package.

### SUMMARY

It is therefore an objective of the present invention to present a structure of light emitted diode package to provide a solution of not only combining the LED chip and the lead frame firmly but also reducing the cost of the LED sealing package.

To achieve the foregoing objectives, a structure of light emitted diode package including a lead frame, a holder, a LED chip, a lower sealing portion and an upper sealing portion. The holder is coupled on an end of the lead frame, the LED chip is disposed on the holder, the lower sealing portion is made by injection molding a first resin material to grab one end of lead frame with the LED chip in order to hold the lead frame, and the upper sealing portion is made by casting by a second resin material to dispose on the top of the lower sealing portion.

### BRIEF DESCRIPTION OF THE DRAWINGS

The structure and the technical means adopted by the present invention to achieve the above and other objects can be best understood by referring to the following detailed description of the preferred embodiments and the accompanying drawings, where:

FIG. 1 is a structural disassembly diagram according to an embodiment of the preferred present invention; and

FIG. 2 is a combination diagram of another embodiment of the present invention.

### DESCRIPTION OF THE PREFERRED EMBODIMENTS

It is to be understood that the following disclosure provides one or more preferred embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not dictate a relationship between the various embodiments and/or configurations discussed.

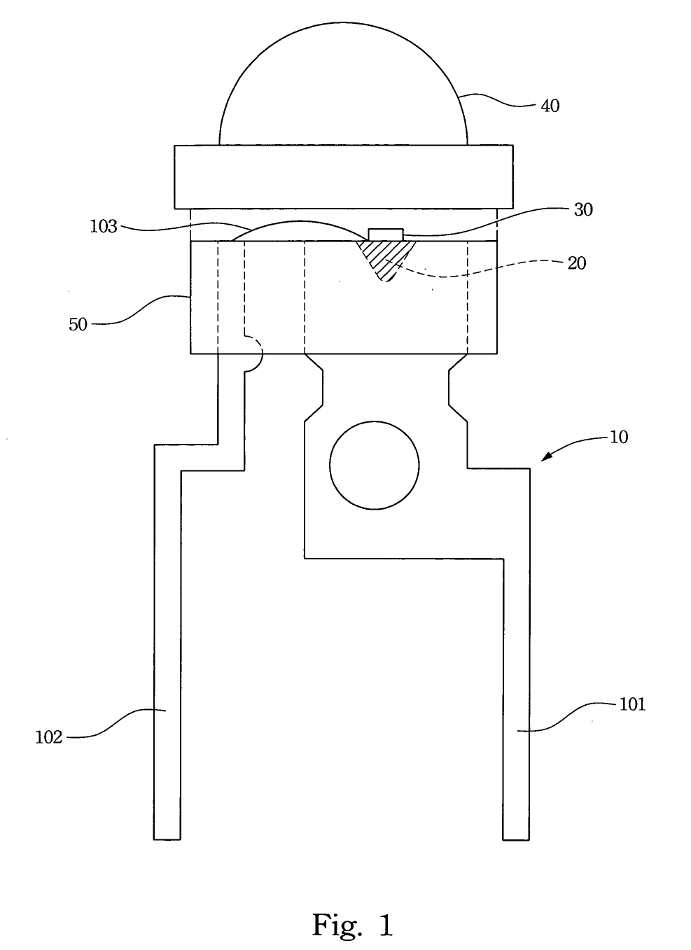

Moreover, in the following description, the relationship of items presented by being described as “top” or “bottom” is based on the diagrams shown in drawings. For instance to FIG. 1, an item numbered as reference 40 is set on the top of another item numbered as reference 50, explaining a positional relationship as disclosed in the drawing, and the remaining relationships of items may be deduced by analogy.

The present invention is to provide a structure of light emitted diode package referred in FIG. 1, a structural disassembly diagram according to an embodiment of the present invention, including a lead frame 10, a holder 20, a LED chip 30, an upper sealing portion 40 and a lower sealing portion 50. The lead frame 10 is made by metal material and has a first foot member 101 and a second foot member 102 on an end thereof. Thus, the lead frame 10 can be electrically connected a circuit (not shown) by the first foot member 101 and the second foot member 102. The holder 20 for holding the LED chip 30 is firmly assembled on an end of the first foot member 101 typically, by a layer of electrically conductive silver glue, and after the LED chip 30 is disposed on the top of the holder 20, the LED chip 30 is electrically connected to an end of the second foot member 102 by an electrically conductive cord 103 or by a manner of “Eutectic Reaction”. Then, the lower sealing portion 50, which may be transparent or opaque, is made by a first resin material in a manner of injection forming (or molding) to dispose on an end of the lead frame 10 with the LED chip 30 and cover the end of the lead frame 10 with the LED chip 30 and the LED chip 30 thereon, thus holding both the first foot member 101 (including the holder 20 and the LED chip 30) and the second foot member 102 tightly and to increase the yield rate. In this embodiment, the first resin material is anticipated to essentially be a rigid material of plastic such as Extruded Polyethylene, EPE; Polyvinyl chloride, PVC; Polystyrene, PS; Extruded polypropylene, EPP and so on. The upper sealing portion 40 is made by a second resin material in a manner of injection forming or casting to dispose on the top of the lower sealing portion 50. In this embodiment, the second resin material is anticipated to essentially be a material of silicone that is able to be against to Ultraviolet light or a material of Epoxy resins that is unable to be against to Ultraviolet light.

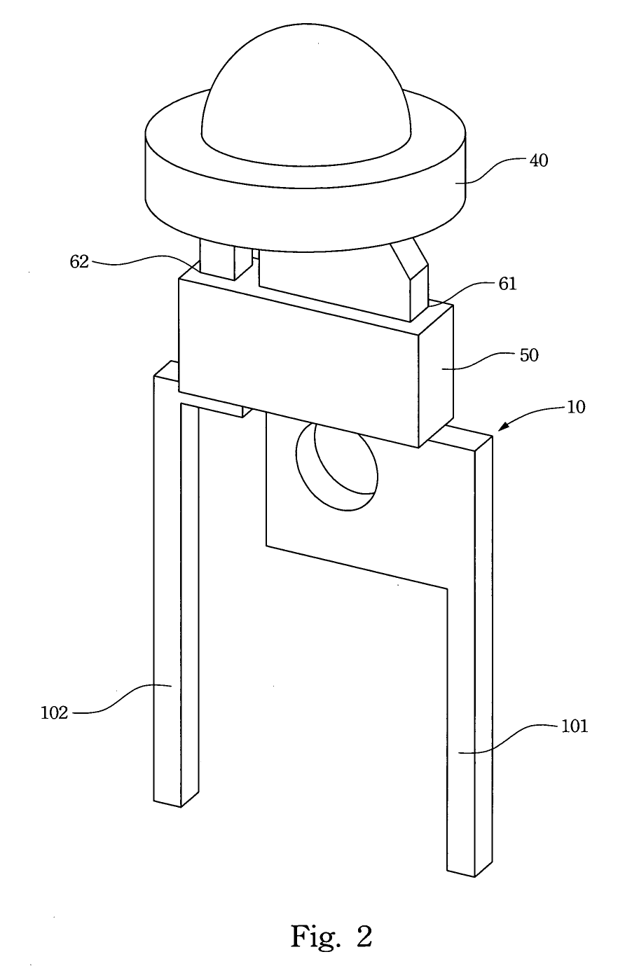

In the present invention the lower sealing portion 50 is not mandatory to be disposed on an end of the lead frame 10 with the LED chip 30 in order to enhance the solidification of the first foot member 101 and the second foot member 102 on the light emitted diode package. Another embodiment of the invention, please refer to FIG. 2, a combination diagram of this embodiment of the present invention, the lower sealing portion 50 can be disposed on the lead frame 10 approximate to a middle of the lead frame 10, that means the lower sealing portion 50 had two openings 61, 62. One opening 61 is pierced by the first foot member 101, and another opening 62 is pierced by the second foot member 102. The lower sealing portion 50 both disposed on the first foot member 101 and the second foot member 102 remaining a distance from the upper sealing portion 40 achieves enhancement of the solidification of the first foot member 101 and the second foot member 102 on the light emitted diode package.

After the lower sealing portion 50 is on the lead frame 10 approximate to a middle thereof, then forming the upper sealing portion 40 on the lead frame 10 with LED chip 30, the upper sealing portion 40 and the lower sealing portion 50 provides a double power in solidifying the light emitted diode package. Such that the light emitted diode package has fewer chances to damage while being carried or moved.

The LED chip 30 consists of several layers such as P-electrode layer, N-electrode layer, P—GaN layer, Multiple Quantum Well (MQW) layer, N—GaN layer and substrate layer. Since the structures and characteristics of those layers are all well known and common knowledge within the current age, and are not the main subject matter of the present invention, that detail of the LED chip 30 will not be disclosed further.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A structure of light emitted diode package comprising:
a lead frame;
a holder coupled on an end of the lead frame;
a LED chip disposed on the lead frame;
a lower sealing portion made by a first resin material in a manner of injection forming to dispose on an end of the lead frame with the LED chip to hold the holder and the LED chip on the lead frame; and
an upper sealing portion made by a second resin material to dispose on the top of the lower sealing portion.

2. The structure of light emitted diode package as claimed in claim 1, wherein the lead frame comprising:
a first foot member having an end thereof coupled on the holder by a layer of electrically conductive glue; and
a second foot member having an end thereof electrically connecting the LED chip by an electrically conductive cord.

3. The structure of light emitted diode package as claimed in claim 1, wherein the lead frame comprising:
a first foot member having an end thereof coupled on the holder by a layer of electrically conductive glue; and
a second foot member having an end thereof electrically connecting the LED chip by a manner of Eutectic Reaction.

4. The structure of light emitted diode package as claimed in claim 1, wherein the second resin material essentially comprises silicone material.

5. The structure of light emitted diode package as claimed in claim 1, wherein the first resin material essentially comprises plastic material.

6. The structure of light emitted diode package as claimed in claim 5, wherein the plastic material is selected from the group consisting of extruded polyethylene, polyvinyl chloride, polystyrene and extruded polypropylene.

7. A structure of light emitted diode package comprising:
a lead frame;
a holder coupled on an end of the lead frame;
a LED chip disposed on the lead frame;
a lower sealing portion made by a first resin material in a manner of injection forming to dispose on the lead frame approximate to a middle thereof to hold the lead frame; and
an upper sealing portion made by a second resin material to dispose on an end of the lead frame with the LED chip to hold the holder and the LED chip on the lead frame.

8. The structure of light emitted diode package as claimed in claim 7, wherein the lead frame comprising:
a first foot member having an end thereof coupled on the holder by a layer of electrically conductive glue; and
a second foot member having an end thereof electrically connecting the LED chip by an electrically conductive cord.

9. The structure of light emitted diode package as claimed in claim 8, wherein the lower sealing portion has two openings, one opening is pierced by the first foot member, another opening is pierced by the second foot member.

10. The structure of light emitted diode package as claimed in claim 7, wherein the lead frame comprising:
a first foot member having an end thereof coupled on the holder by a layer of electrically conductive glue; and
a second foot member having an end thereof electrically connecting the LED chip by a manner of Eutectic Reaction.

11. The structure of light emitted diode package as claimed in claim 7, wherein the second resin material essentially comprises silicone material.

12. The structure of light emitted diode package as claimed in claim 9, wherein the first resin material essentially comprises plastic material.

13. The structure of light emitted diode package as claimed in claim 12, wherein the plastic material is selected from the group consisting of extruded polyethylene, polyvinyl chloride, polystyrene and extruded polypropylene.
